(19) United States
(12) Patent Application Publication
(10) Pub. No.: US 2005/0190253 A1
(43) Pub. Date: Sep. 1, 2005

(54) Structured polmer substrate for ink-jet printing of an oled matrix

(76) Inventors: Paulus Cornelis Duineveld, Eindhoven (NL); Johan Frederik Dijksman, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/502,961

(22) PCT Filed: Jan. 29, 2003
(86) PCT No.: PCT/IB03/00307

§ 371 Date: Jul. 29, 2004

(30) Foreign Application Priority Data
Feb. 1, 2002 (EP) 02075423.0

(51) Int. Cl. B41J 3/407; H01J 1/62; G03C 5/00; G03F 9/00; H01J 63/04

(52) U.S. Cl. 347/106; 313/504; 313/505; 430/321; 430/7

(57) ABSTRACT

The present invention provides a matrix substrate for controlling liquids printed on the substrate and a method of fabrication of such. According to the invention, a substrate holding a matrix of pixels for receiving and holding printed liquids is fabricated in a deformable and flexible polymeric material which allows for raised structures (barriers) separating the pixels to be formed in the substrate material itself. This renders possible a number of new methods of fabrication for the fabrication of matrix substrates, e.g. for use in polyLED displays. The materials and methods of fabrication according to the invention further remove a number of limitations in the freedom of design known from materials and methods of fabrication according to the prior art. This leads to the possibility of barrier profiles with overhanging structures, improved resolution and new dimension ranges.

### FIELD OF THE INVENTION

The present invention relates to pixel assemblies on a substrate for controlling liquids printed on the substrate, ard more particularly to methods of manufacturing, and materials for, such pixel assemblies.

Organic electroluminescent displays such as PolyLEDs are flat panel displays consisting of a matrix of pixels having an anode, a cathode, and a thin layer of semi-conducting material, each pixel forming a light emitting diode. The lateral dimensions of pixels are related to the resolution of the display, e.g. a 100 pixel per inch (100PPI) monochrome display has 254 by 254 micron pixels. A 127 PPI full color display has 66.7 by 200 micron pixels. The thin layer of semi-conducting material is about 0.3 micron thick. The compounds in each pixel are typically deposited through the process of ink-jet printing after having been dissolved in a solvent. In order to control the printed liquid, pixels are defined as a matrix of small compartments separated by barriers formed on a substrate. By printing in such a pixel or compartment, the printed material will be confined to a pixel.

### BACKGROUND OF THE INVENTION

In the prior art, the formation of structures in thin-film resist layers on glass substrates by photolithography has been the preferred process for fabricating matrix substrates for displays. Photolithography is a well-known technique for processing fine structures and thin layers on glass or silicon substrates. Photolithography uses spin coating as the process to produce a thin layer, which is structured photolithographically. The materials used for color PolyLED displays cannot be spun on top of each other, rendering the production of color displays virtually impossible in this way.

Typically, ink-jet printing is the preferred technique when an active compound dissolved in a solvent is to be deposited on the surface of a substrate. It is important that printed liquids do not flow over barriers and contaminate, or mix with, liquid in adjacent pixels as this will cause the colors in a light-emitting area to be changed in an uncontrollable way. The semi-conducting structure is formed after drying-in of the wet layer.

U.S. Pat. No. 6,143,450 discloses a typical fabrication of a color filter substrate according to the prior art. An alignment mark and a matrix of pixels separated by barriers are simultaneously formed on a glass substrate. The matrix is formed by depositing one or more thin-film layers which are patterned into a predetermined shape by photolithography. Next, an ink receptive layer is formed on the matrix after which the colors are printed on the ink receptive layer. The alignment mark is used to ensure the precision of the printed droplets in order to avoid mixing of colors, the geometry being such as to optimize the effect of surface wetting and planarized infill.

The glass substrates most commonly used are rigid and non-deformable. The structuring to form barriers is therefore fabricated by depositing layers of photo-resist materials and forming barriers in the photo-resist by photolithography. This method of fabrication limits the freedom to design barriers as well as the obtainable resolution and heights of the structures.

### SUMMARY OF THE INVENTION

It is an object of the present invention to provide a new and inventive method of fabrication of substrates having pixels for receiving and holding liquids, the method providing freedom to design barriers and providing a sub-micron resolution.

It is a further object of the present invention to provide a method of fabrication of a substrate having pixels for receiving and holding liquids, said method providing a simple and cheap mass production of display substrates.

It is still another object of the present invention to provide a substrate having pixels for receiving and holding liquids, the pixels being separated by barriers which are less inclined to allow liquid to spill over between adjacent pixels, thereby being less sensitive to drop placement accuracy and allowing for two adjacent pixels to be filled at the same time without mixing.

The present invention as described in claims 1 through 22 provides methods for fabricating articles, and tools to be used in the fabrication of articles, which articles comprise substrates having structures for receiving and holding droplets or lines of liquid for use in the deposition of materials using ink-jet printing techniques. It is an important feature of the present invention that the substrates and at least part of the structures are formed in the same polymeric material. This allows for new methods of fabrication of such articles, which have a number of advantages. In the following, the main aspects of the invention and their advantages will be described in greater detail.

According to a first aspect, the present invention provides a method for fabricating an article for receiving and holding droplets or lines of liquid-holding deposition material, the method comprising the steps of:
providing a shaping tool having a surface part with a predetermined structure,
providing a deformable polymeric material, and
forming a structured surface part of the material by processing the deformable polymeric material using the shaping tool thereby forming a predetermined structure comprising a grid of raised structures defining a matrix of compartments in said surface part of the deformable polymeric material, said compartments being adapted to receive and hold droplets or lines of liquid deposition material, the structured surface part of the deformable polymeric material at least substantially being an imprint of the predetermined structure of said surface part of the shaping tool.

Preferably, the deformable polymeric material, at least after the step of forming the structured surface part, forms a self-supporting substrate. Thereby, the article for receiving and holding droplets or lines of liquid comprises a self supporting substrate of said material with a predetermined structure formed in a surface part of said material. When a material is said to form a self-supporting substrate, it is meant to state that the material does not necessarily need to be held by a supporting base (such as a glass substrate) in order to maintain its structure or shape. Thus, the material is not a thin film deposited on another substrate, but it is not meant to exclude that the material may be held by another plate or substrate, e.g. to secure a proper handling.

It is an essential feature of all aspects of the present invention that the grid of raised structures defining the compartments is formed in the deformable polymeric material so that the raised structures and the part of the article holding the raised structures are formed in the deformable polymeric material. Thus, the barriers on the substrate that are needed to control the liquid deposition material can be made out of the substrate material itself, because this material is a deformable polymeric material. This can eliminate the use of photolithographic process steps to make the barriers with additional resist material. The deformability and flexibility of polymeric materials allows for raised structures being formed in shapes not feasible in the materials and methods of fabrication of the prior art.

It is an advantage of the method of fabrication according to the first aspect that it allows for a fast and cost-effective mass production of substrates. It is another advantage of the method that structures can be formed with a sub-μm resolution without any particular modifications in the fabrication process. It is another advantage that the replication process offers the possibility of shapes that are not possible with lithography.

The claimed method is to be compared with the materials and the method of fabrication according to the prior art. According to the prior art, the materials layers to form the structures are deposited on a glass substrate. These layers are structured by illuminating a resist through a phase mask followed by removal of non-illuminated regions through etching. Standard photolithographic equipment has a limited resolution of approximately 10 μm. To obtain an increased resolution, expensive extra equipment (steppers) must be incorporated in the fabrication process.

In the method of fabrication according to the first aspect, a fabrication tool (a master, form, stamp, etc.) is fabricated, after which the replication of many substrates is a cheap and fast process.

Preferably, the shaping tool is a moulding form, in which case the step of forming a structured surface part of the material comprises the step of applying the deformable polymeric material into the moulding form. Alternatively, the shaping tool is an embossing stamp, in which case the step of forming a structured surface part of the deformable polymeric material comprises the step of embossing the deformable polymeric material with the embossing stamp. In another alternative, the shaping tool is an extrusion form, in which case the step of forming a structured surface part of the deformable polymeric material comprises the step of extruding the deformable polymeric material with the extrusion form.

Thus, according to a second aspect, the present invention provides a shaping tool for use in the fabrication method according to the first aspect, the shaping tool having a surface part with a predetermined structure corresponding to a shape, profile, and intended function of the substrate.

According to a third aspect, the present invention provides another method for fabricating an article for receiving and holding droplets or lines of liquid deposition material, the method comprising the steps of:
providing a photopolymerisable material, and
forming a structured substrate of the photopolymerisable material by photopolymerisation, comprising at least the steps of:
illuminating one or more first layers of said photopolymerisable material in a first predetermined pattern,
illuminating one or more second layers of said photopolymerisable material in a second predetermined pattern,
   wherein the illuminated first layers form a substrate, and wherein the illuminated second layers form a grid of raised structures defining a matrix of compartments on said substrate, said compartments being adapted to receive and hold droplets or lines of liquid deposition material.

It is an advantage of the method according to the third aspect that structures of almost any shape can be fabricated. This allows for a very detailed structuring of profiles of at least some of the structures which will greatly enhance the reception and holding of printed liquids. It is another advantage of the method that structures can be formed with a sub-μm resolution without any particular modifications in the fabrication process.

According to a fourth aspect, the present invention provides an article for receiving and holding droplets or lines of a liquid deposition material, the article comprising a substrate formed by a deformable polymeric material, the substrate having a surface part comprising a grid of raised structures, the grid defining a matrix of compartments being adapted to receive and hold droplets or lines of liquid deposition material.

According to a fifth aspect, the present invention provides an article for receiving and holding droplets or lines of liquid deposition material, the article comprising a substrate formed by a deformable polymeric material and having a surface part comprising a grid of raised structures formed at least partially in the substrate, at least some of the raised structures having a characteristic profile, the grid defining a matrix of compartments, wherein the raised structures enable the compartments to receive and hold droplets or lines of liquid deposition material, and wherein the grid, the raised structures, and the characteristic profiles are formed by imprinting a shape of a shaping tool to the deformable polymeric material by the fabrication method of embossing, blow moulding, injection moulding, or extrusion.

Polymeric materials are organic materials with at least a carbon molecule in the backbone. These materials can be differentiated from inorganic materials by comparing the molecular weight of the material. A polymer has a mass average molecular weight that ranges from thousands to several million grams/mole. An inorganic material, like glass or metal has a molecular weights that is typically much lower. Alternatively, polymeric materials can be separated from other materials by their elastic modulus. For polymeric materials, the elastic modulus is smaller than 20 gigaPascal, while glasses, metals, and other inorganic substrate materials have an elastic modulus larger than 35 gigaPascal.

As a result of their deformability and flexibility, polymeric materials are particularly suitable for the fabrication methods and articles according to the present invention. The deformability is essential in the shaping process which may be performed at high pressure and/or temperature in order to obtain an even higher deformability and flexibility. Also, the flexibility is essential in the formation of overhanging structures in the surface, where the polymeric material has to flex in order to separate the substrate and the shaping tool after shaping.

Preferably, at least some of the raised structures on the surface part of the substrate are formed with a profile which allows for a compartment to hold a volume of the liquid deposition material larger than a volume of the compartment, and which allows two adjacent compartments to be completely filled without mixing the liquid deposition materials. Raised structures performing the function of separating two adjacent compartments will also be referred to as barriers.

A compartment is completely filled when filled to the point where adding more liquid would result in liquid flowing to an adjacent compartment. How much liquid a completely filled compartment can hold, of course, depends on the volume of the compartment, generally defined as its base area multiplied by the height of the lowest barrier (assuming perfectly vertical barriers, it is considered common knowledge to calculate the volume of any shape). Due to surface tension in the liquid to be held, a compartment may hold an amount of liquid of a volume which is larger that the volume of the compartment. This may be expressed as a filling ratio:

$${R}_{filling} = \frac{Maximum volume held by compartment}{Compartment volume} .$$

The filling ratio depends on a number of parameters of the liquid. For a given liquid, the filling ratio also depends on the material composition of the top of the barriers forming the compartment and on the geometrical shape of a profile of the top of the barriers.

In barriers of the prior art, the liquid surface of a completely filled compartment extends to the far edge of the barrier, and, therefore, two adjacent compartments cannot be filled at the same time.

Thus, it is an advantage of the methods for fabricating articles and the barriers that the profiles of the at least some structures can be formed with a high resolution and with a great variety of very detailed shapes.

In order to overcome the problems of matrix substrates of the prior art, at least some of the raised structures may form elongated barriers separating a first and a second adjacent compartment. In a number of preferred embodiments, the profiles of said at least some raised structures have at least a first and a second edge, the first edge being formed by a top surface part and a side surface part facing away from the second compartment, and the second edge being formed by a top surface part and a side surface part facing away from the first compartment, the first edge being closer to the second compartment than the second edge, and the second edge being closer to the first compartment than the first edge. In other words, the barriers are split along their center line, thereby forming two raised formations or sub-barriers so that each compartment has an edge pointing away from the compartment in its own half of the barrier. Preferably, the top surface parts are at least substantially parallel to the substrate, and the top surface parts and side surface parts forming the first and the second edge intersect at an angle smaller than 90° so as to form a sharp-pointed edge.

It is an advantage of the preferred embodiments that they allow a compartment to have a larger filling ratio, R_{filling}. As will be described in greater detail later, surface tension in liquid surfaces enables a liquid droplet to overhang an edge in the barrier, thereby increasing the maximum volume held by the corresponding compartment. The degree to which the liquid can overhang the edge depends on the properties of the liquid as well as on the profile of the barrier. By making sharp-pointed edges in the barrier profile which points away from a compartment, the compartment will be able to hold a larger volume of liquid in comparison to barriers according to the prior art.

Profiles of at least some of the structures rise to a height that is higher than 10 μm, 5 μm, 2 μm, 1 μm, or 0.5 μm. Also, the ranges of heights of structures on a substrate according to the present invention are much larger than for a substrate according to the prior art. According to methods of fabrication in the prior art, structures preferably have the same height. Since the structures are formed by masking and etching, several masking and/or etching steps are typically required to make structures with different heights. This is due to the fact that material is removed by etching at a given rate for a given material and etching technique.

Different structures on a substrate according to the present invention may have different heights in large ranges. When a master has been formed, the geometry and dimensions of the structures have little influence on the replication. The structures preferably consist of barriers, each of which may comprise a detailed profile consisting of two or more sub-barriers separated by a gap.

The dimensions of the barriers (width, height of barrier and sub-barrier) may vary depending on the display type, i.e. a monochrome display or a full color display.

Typically, one is interested in minimizing the width of the barriers, especially for the full color displays, because in that case the fill factor (i.e. the size of the active area of the pixel) is important. On the other hand, the dimensions of the barriers should not be made too small since this would cause the liquid to mix too easily between different pixels.

The width of the barriers is preferably smaller than 40 μm, or preferably smaller than 20 μm, or more preferably smaller than 10 μm, or even more preferably smaller than 5 μm.

The height of the barrier is preferably larger than 2 μm, 5 μm, or 10 μm. However, since the fabrication techniques and materials of the present invention allow for much higher barriers, the barriers in a preferred embodiment are higher than 20 μm, 30 μm or even higher than 50 μm.

The gaps between sub barriers are preferably smaller than 20 μm, such as smaller than 10 μm, 5 μm, or 2.5 μm. The height of the sub-barriers is preferably ¼ of the height of the total barrier and more preferably ½ of the height of the total barrier and even more preferably ¾ of the height of the total barrier.

According to the various objects, the invention allows matrix substrates to have much higher structures than in the prior art. In a preferred embodiment, liquids in neighboring compartments are efficiently separated by forming very high barriers in that at least some of the raised structures rise to a height of at least 10 μm, such as at least 20 μm, from the surface part of the substrate.

In another preferred embodiment, a surface part of a top part of a raised structure is formed by a hydrophobic material so as to make the top of the barrier non-wetting and resist overflowing. Preferably, such a surface part of a top part of a raised structure is formed by multi-cavity injection moulding. Another way of forming a non-wetting top of a barrier may be for the top part of a barrier to comprise a pattern of small structures (pillars). The pillars preferably have cross-sectional areas smaller than 10 μm², such as smaller than 1 μm², or smaller than 0.1 μm². The height of the pillars is preferably larger than half of the square root of the cross-sectional area, such as larger than the square root of the cross-sectional area, preferably larger than 3 times the square root of the cross-sectional area.

This invention disclosure describes a substrate architecture and methods of fabrication of such, for ink-jet printing on plastic. The invention may be applied in the fabrication of both active and passive matrix displays. The invention will be illustrated for ink-jet printing polymeric layers for a polymeric electroluminescent matrix display PolyLED, however it can be used for all applications in which an active material has to be applied with sa elective printing technique on a plastic substrate.

### BRIEF DESCRIPTION OF THE DRAWINGS

FIG. 1 shows a top view of a general matrix substrate.

FIG. 2 shows an enhanced cross-sectional view of the matrix substrate of FIG. 1.

FIG. 3 shows a cross-sectional view of a matrix substrate with different liquid levels.

FIG. 4 shows an enhanced cross-sectional view of the matrix substrate of FIG. 3 with only one liquid level.

FIG. 5A shows an enhanced cross-sectional view of a barrier, a deposited amount of liquid and angles in relation. FIG. 5B shows an enhanced cross-sectional view of a barrier, a deposited amount of liquid and a relating angle.

FIG. 6A to D describes the contact and wetting angles between barriers and liquids on a substrate.

FIGS. 7,8,9,10 and 11 show embodiments of different barrier profiles on matrix substrates.

FIG. 12 shows an embodiment of a rectangular barrier profile, a deposited amount of liquid and a barrier height.

FIG. 13 shows a cross-sectional view of a barrier profile with different wetting characteristics.

FIG. 14 shows an enhanced cross-sectional view of a barrier profile with poor wetting characteristics.

FIG. 15 shows a cross-sectional view of a barrier profile with different wetting characteristics.

### DETAILED DESCRIPTION OF THE DRAWINGS

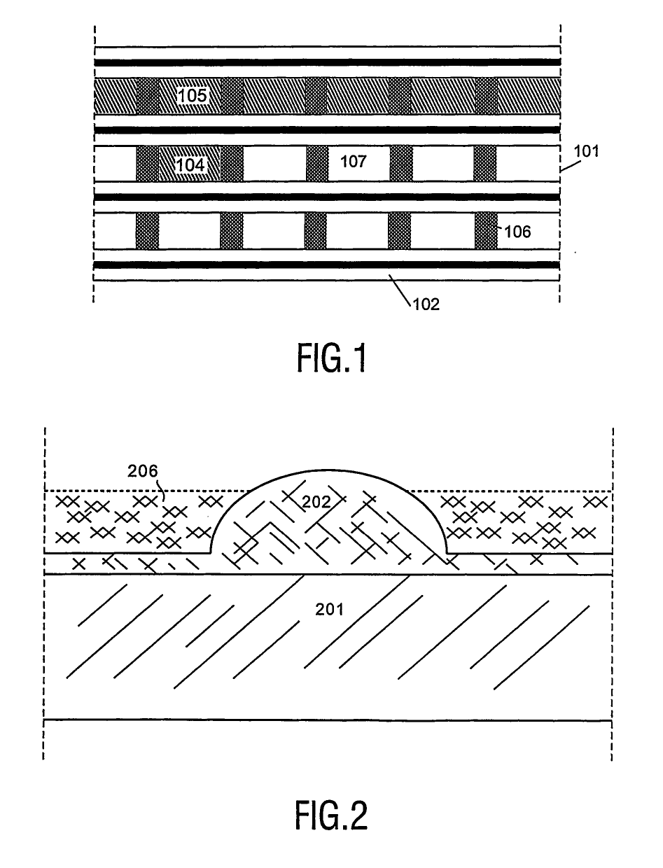

FIG. 1 shows a top view of a general matrix substrate 1, with a grid of barriers forming a matrix of compartments or pixels 7. The compartments 7 are formed by horizontal barriers 2 and vertical barriers 6. A row of compartments formed in between the horizontal barriers 2 are hereinafter referred to as channels 5. When a channel 5 has been printed, a liquid 4 is distributed throughout the entire channel 5.

FIG. 2 shows an enhanced cross-sectional view of a barrier of a matrix substrate 201 according to the prior art, such as the matrix substrate of FIG. 1. The cross-section of a horizontal barrier 202 is shown and a side-view of a vertical barrier 206 is also presented in order to clarify the physical layout. The barriers are typically formed by structuring a deposited photo-resist layer by photolithography. Due to the poor resolution in the photolithography process, no specific profile structure can be formed in the barriers 202 and 206.

The matrix substrates according to the present invention are fabricated in a polymeric or plastic material which is deformable, flexible and provides the possibility of fabrication methods other than the standard photolithography of photoresist on a glass substrate.

Polymeric or plastic matrix substrates can be formed, shaped and structured using processing techniques known from the field of processing polymeric or plastic materials. A person skilled in the art of processing polymeric or plastic materials can use techniques such as embossing, blow moulding, injection moulding, extrusion, calendering, and photo-polymerization for forming structured substrates, such as matrix substrates in polymeric or plastic materials. These processing techniques provide a better resolution and replicability than photolithography. Also, the combination of the new processing techniques and polymeric or plastic materials, being more flexible and less fragile than photoresist materials and glass, makes it possible to form more complex structure designs.

Structuring a Polymeric or Plastic Substrate by Embossing

Embossing is a method of transcribing the structure on a stamp onto a plastic substrate by applying a high pressure during a certain amount of time. The pressure is so high that the transcription takes place by plastic deformation of the substrate material in order to comply with the structure on the stamp. To shorten the pressure time, the temperature during pressing has to increase almost to the glass transition temperature of the substrate material. The resolution is comparable to the resolutions reached in optical disk manufacturing, with pitches down to 0.5 micron and heights of the barriers up to 100 nm. Embossing is usually carried out on flat substrates.

Structuring a Polymeric or Plastic Substrate by Blow/Injection Moulding

Injection moulding is a mass manufacturing method of making products out of polymeric material by pressing molten plastic into a mould. Melting of the material is done in a reciprocating screw extruder. During melting, the screw moves backwards collecting the molten material in front of the screw, and during filling of the mould, the screw moves forwards acting like a piston. The mould is kept at a low temperature to allow for rapid cooling. After filling, the screw holds the material in the mould under high pressure to compensate for shrinkage during cooling. At the moment when a substantial amount of the material is below the glass transition temperature, the mould is opened and the product is taken out. Directly upon closure of the mould, the next product can be made. For good transcription of the structure on the inside of the mould to the product, the wall temperature should be close to the glass transition temperature. The resolution can be comparable to the resolutions reached in optical disk manufacturing, with pitches down to 0.5 micron and heights of the barriers up to 100 nm. Injection moulding allows for the production of products of any shape.

Structuring a Polymeric or Plastic Substrate by Extrusion/Calendering

Extrusion is a continuous process. Molten material is pressed out of a slit and cooled. The shape of the slit is transferred to the continuous sheet. Only structuring perpendicularly to the motion of the sheet is possible. As the material has to be in the molten state during pressing out of the slit, some rounding of sharp edges will occur. Calendering is a method of transcribing small structures from a cylindrical rotating body on a thin sheet of material under high pressure. In principle one can attain resolutions comparable to those obtained by embossing or injection moulding.

Structuring a Polymeric or Plastic Substrate by Photopolymerization

The so-called 2P process (Photopolymerization) utilizes the possibility of depositing a low-molecular monomeric fluid of low viscosity, on to the surface of a complex structure and initializing the polymerization by UV light (UV curing). This method is more complex than embossing, injection moulding, extrusion or calendering, but the resolution is almost molecular and the freedom of shaping is enormous.

Hence, using polymeric or plastic materials for matrix substrates allows for the advantages of the above-mentioned processing techniques to significantly improve the matrix substrates for receiving and holding printed liquids. The utilization of these advantages makes it possible to design the detailed structure of the compartments and barriers capable of solving the problems encountered by the prior art matrix substrates.

In the following sections, the design and the functionality of the compartments and barriers according to the present invention will be described in relation to a preferred embodiment, after which a number of other preferred embodiments will be presented.

The pixel shape, as sketched in FIG. 1, need not be rectangular. It can also be rectangular with rounded corners, circular or any other shape.

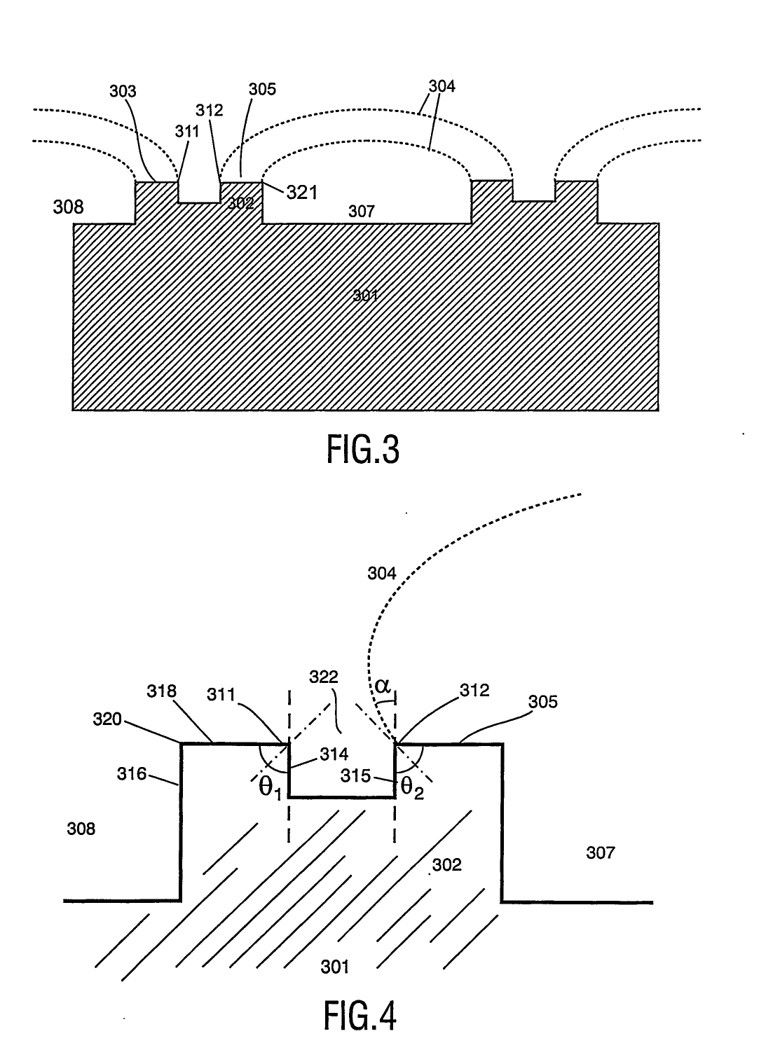

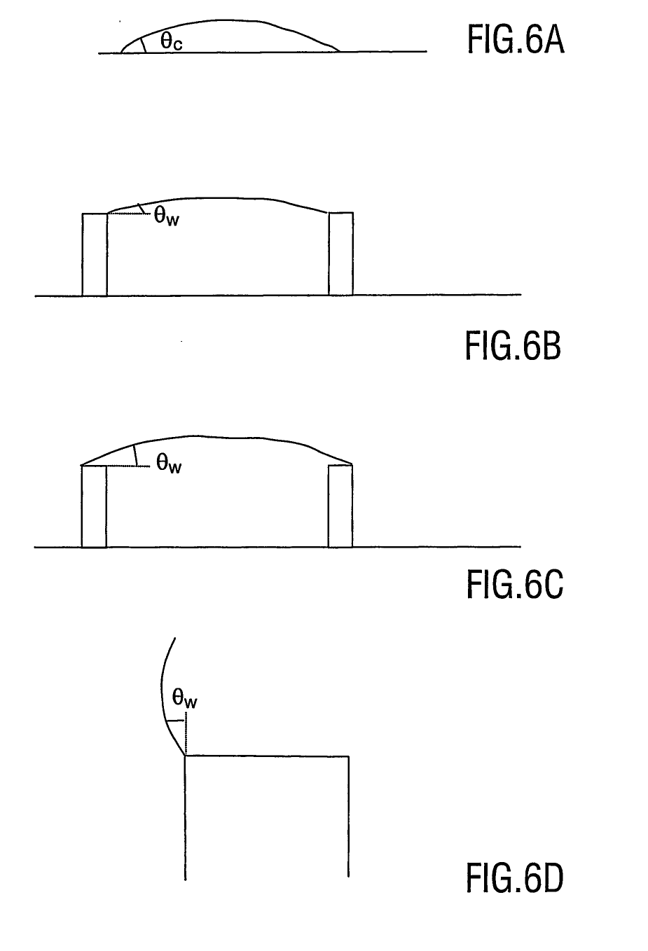

FIG. 3 shows a cross-section of a matrix substrate 301 according to the invention. As can be seen, barriers 302 are formed in the substrate and are part of the substrate. The upper part of the barrier 302 has a first raised formation or sub-barrier 303 for delimiting a compartment 308 and a second raised formation or sub-barrier 305 for delimiting a compartment 307. The barrier and the sub-barrier are formed in order to prevent liquid 304 from spilling over into an adjacent compartment 308. The walls 303 and 305 are of rectangular shape with edges 311 and 312. The Figure shows the liquid 304 in two states, a first state in which the compartment 307 is not completely filled because the liquid 304 is contained by an inner wall edge 321, and also in a second state in which the liquid 304 is contained by the edge 312 facing away from the compartment. In the second state, the liquid 304 wets only the top surface part of the wall 305 closest to the compartment 307 holding the liquid. Also, the edge 312 precluding the liquid from further spreading is an edge of the wall 305 delimiting the compartment. Liquid completely filling compartment 307 will be contained by the edge 312 facing away from compartment 308, without interfering with the liquid in completely filled compartment 307. Walls 303 and 305 divide the barrier 302 into two virtually separate barriers. The degree to which liquids may overhang edges of barriers are discussed further in relation to FIGS. 6A-D.

FIG. 4 shows an enhanced view of the barrier in FIG. 3. The angles θ₁ _{and θ}₂ describe the shape of the edges 311 and 312, each facing away from their closest respective compartment. With liquid 304 completely filling compartment 307, surface tension allows the liquid surface to overhang the edge 312, creating an angle α with the side surface part of the wall 315 facing away from the compartment 307. The angle θ is primarily determined by the properties of the liquid and the material composition of the barrier. Thus, by inclining the side surface part facing away from the compartment while keeping the top surface part horizontal, the amount of overhanging liquid can be increased. The more sharp-pointed the edge 312 (the top surface part still being at least substantially horizontal), the more liquid can be held by a compartment of a given size.

A barrier 302 as shown in FIG. 4 has a top part consisting of two sub-barriers situated on each side of the barrier. Each wall has two side surface parts 314 and 316, a top surface part 318, and an inner and an outer edge 311 and 320, respectively. The edge 320 faces the compartment 308, and 311 faces the compartment 307. The edge 311 is formed with an angle θ between the side surface part 314 and the top surface part 318. Hence, the design incorporates two opposite side surface parts 314 and 315 forming a gap in the top surface of the barrier. In case the maximum amount of liquid 304 is exceeded and liquid flows over, the gap 322 will function as a drain between the first and the second wall. This eliminates the risk of a liquid spilling over into an adjacent compartment and mixing, of the spilled liquid with the liquid of the adjacent compartment. If any, mixing occurs it occurs in an inactive area between the compartments in the gap.

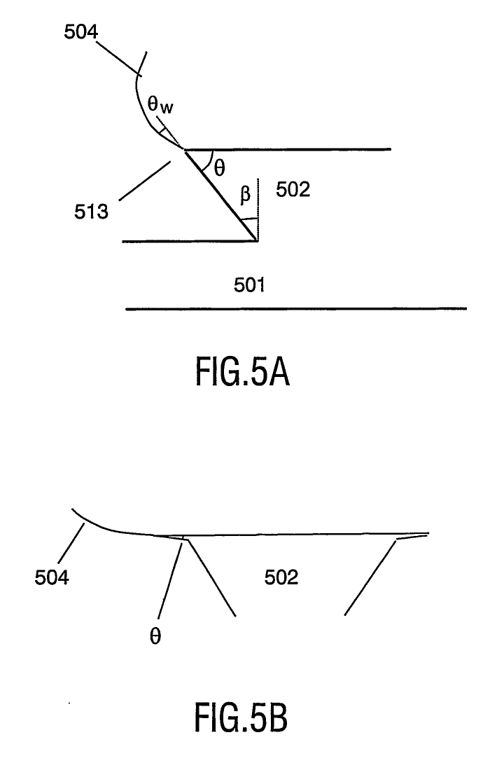

In another type of preferred embodiments shown in FIGS. 5A and B, the edge facing away from a compartment has been formed with a more sharp-pointed edge. In particular, the angle β of the barrier 502 with the planar surface of the substrate 501 has been decreased while keeping the upper surface part of the barrier horizontal; this corresponds to decreasing the angle θ of the edge 513 of the barrier (or sub-barrier).

FIG. 5A shows a part of a barrier 502, a deposited amount of liquid 504 and angles θ_{w} and β in relation. The angle θ_{w} corresponds to the liquid's wetting angle with the barrier edge 513.

The contact angle θ_{c} of a liquid is defined as the angle a drop of liquid makes on a substrate, as shown in FIG. 6A. The contact angle θ_{c} can be described by

$$Cos {θ}_{c} = \frac{{γ}_{sv} - {γ}_{sl}}{σ} ,$$

where σis the surface tension of the liquid, γₛᵥ and γₛₗ are the substrate-vapor and substrate-liquid energies per area. This formula teaches that θ^{c} can be increased either by increasing the surface tension of the liquid or by changing the properties of the substrate.

The wetting angle θ_{w} is defined as the angle the liquid makes with the substrate. This angle can be smaller than the contact angle, as is sketched for instance in FIG. 6B.

The wetting angle θ_{w} is smaller than the contact angle θ_{c}, hence the liquid does not wet the side barrier.

When the volume of liquid is increased and θ_{w}>θ_{c}, the side barrier would be wetted, resulting in the situation of FIG. 6C. The liquid will now wet the side barrier, if the angle the liquid makes with the substrate is larger than the contact angle, which is sketched in FIG. 6D.

When the angle of the barrier β is increased at a fixed value of θ, it is obvious that the amount of liquid that can be put in a channel can be increased. For instance, when β=0 and θ=0.1 rad., the angle of the liquid with the horizontal is π+0.1. When β=1, then the angle of the liquid can be increased to π+1 in a 2-D situation.

Thus, FIGS. 5A and 5B illustrate barriers 502 with profiles shaped specifically to increase the amount of liquid 504 that can be held by the compartment.

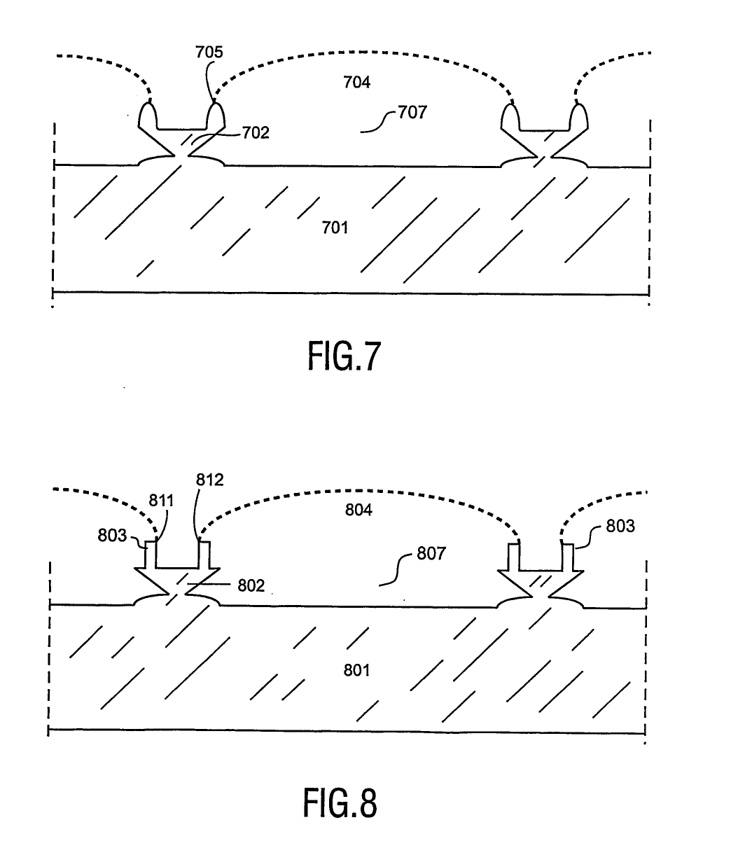

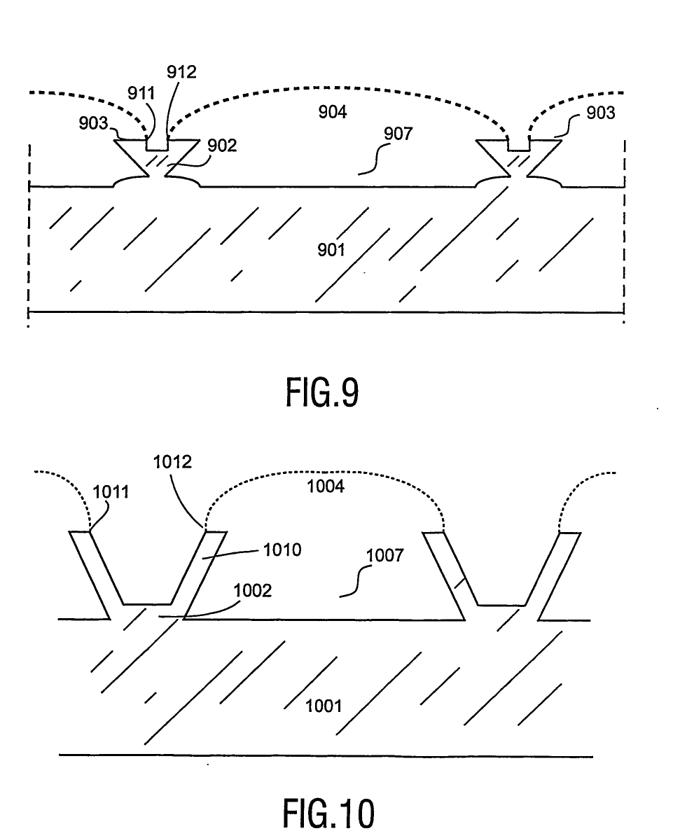

FIG. 7 illustrates a cross-section of a profile of another barrier 702 on a substrate 701 according to the invention. The barrier is formed in the substrate material and the profile is shaped in accordance with a preferred embodiment of the present invention. The barrier 702 is a part of the substrate 701. The upper part of the barrier 702 has two raised formations or sub-barriers 705 formed with a profile which allows for a compartment 707 to hold a volume of the liquid which is larger than a volume of the compartment and which allows two adjacent compartments to be completely filled without mixing the liquids. The sub-barriers 705 have smooth concave profiles in comparison with similar formations 305 in FIG. 4. The sub-barrier may have any shape.

FIG. 8 illustrates a cross-section of a profile of another barrier 802 on a substrate 801 according to the invention. The barrier is formed in the substrate material and the profile is shaped in accordance with a preferred embodiment of the present invention. The upper part of the barrier 802 has two raised formations or sub-barriers 803 The barrier 802 and the sub-barriers 803 are formed in order to prevent the liquid 804 in compartment 807 from spilling over into an adjacent compartment. The sub-barriers 803 are of rectangular shape.

FIG. 9 illustrates a cross-section of a profile of another barrier 902 on a substrate 901 according to the invention. The barrier is formed in the substrate material and the profile is shaped in accordance with a preferred embodiment of the present invention. The upper part of the barrier 902 has two raised formations or sub-barriers 903. The barrier 902 and the sub-barriers 903 are formed in order to prevent the liquid 904 in compartment 907 from spilling over into an adjacent compartment.

FIG. 10 illustrates a cross-section of a profile of another barrier 1002 on a substrate 1001 according to the invention. The barrier is formed in the substrate material and the profile is shaped in accordance with a preferred embodiment of the present invention. The barrier consists of two outward leaning barrier walls 1010. The barrier 1002 and the outward leaning walls 1010 are formed in order to prevent the liquid 1004 in compartment 1007 from spilling over into an adjacent channel.

FIG. 11 shows a cross-section of a profile of another barrier 1102 on a substrate 1101 according to the invention. The barrier is formed in the substrate material and the profile is shaped in accordance with a preferred embodiment of the present invention. The inward leaning and overhanging walls create very sharp-pointed edges as well as a large volume in the gap separating the walls.

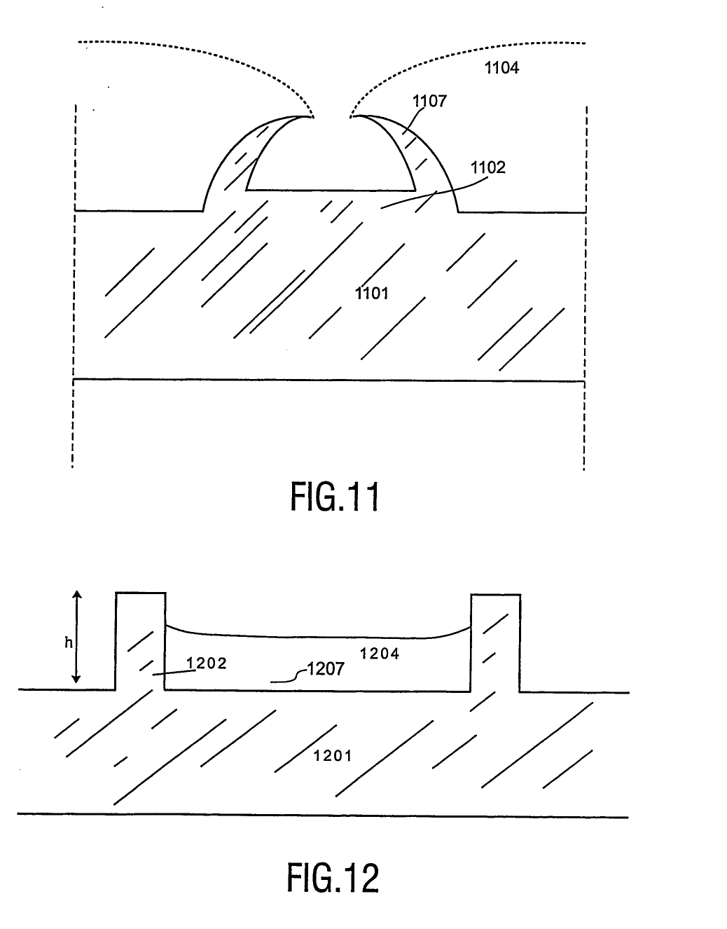

FIG. 12 shows a cross-section of a substrate 1201 according to the invention, showing a profile of a rectangular barrier 1202. The rectangular barrier 1202 is formed in the substrate 1201 in accordance with the present invention. The choice of material and method of fabrication enable the formation of very high barriers, such as barriers with a height h of 25 μm. Consequently, the volume of compartment 1207 is significantly increased without increasing the base area of the compartment. Since the liquid 1204 does not completely fill the compartment, there is no liquid surface above the top part of the barrier, which can spill over to an adjacent compartment. Thus, no detailed structuring of the top part of the barrier is necessary.

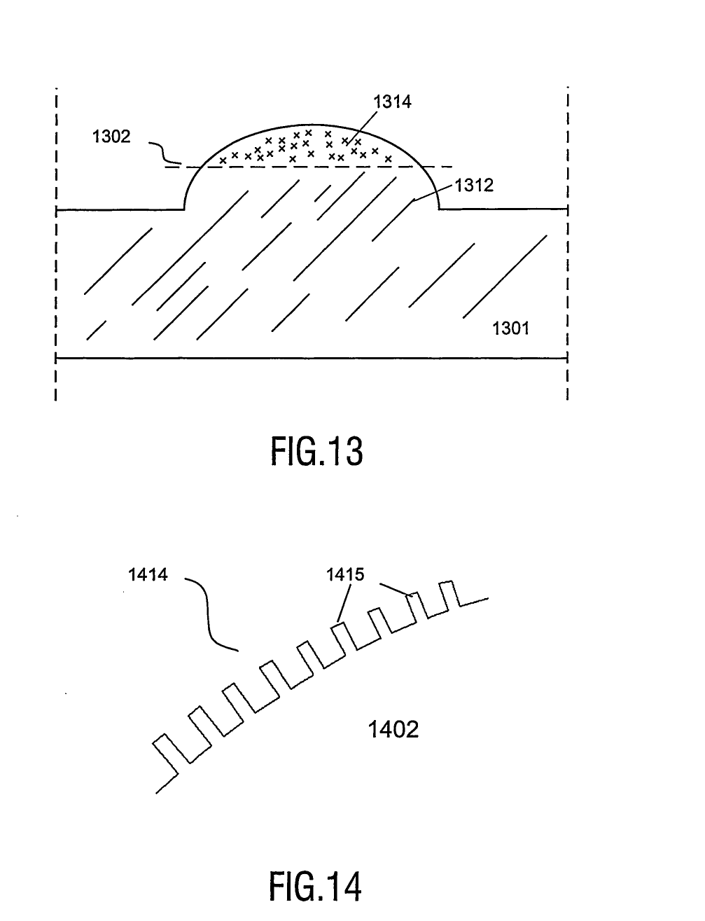

FIG. 13 shows a cross-section of a profile of another barrier 1302 on a substrate 1301 according to the invention. The barrier is in this case formed with different wetting properties. The surface of a base part 1312 of the barrier 1302 is characterized by good wetting properties, whilst the surface of a top part 1314 of the barrier 1302 is characterized by poor wetting properties. The effect of this is similar to the structuring of the top part of the barrier, namely that the liquid surface recedes towards the compartment forming a large contact angle with the poorly wettable material.

The wetting properties of the material should be chosen to fit the liquid. In general, hydrophilic materials such as nylon 6, nylon 11, nylon 6, 6 nylon 10, 10 or polycarbonate have good wetting properties for polar liquids and poor wetting properties for non-polar liquids. Similarly, a hydrophobic material surface having poor wetting properties for polar liquids and good wetting properties for apolar liquids can be obtained by applying a fluorine-containing monolayer on the barrier with a CF4 treatment. In general, materials on which the liquid has a high contact angle should be used. Such materials could be polyethylene, polypropylene, polyisobutylene or polystyrene. In the embodiment in which the good and the poor wetting properties are obtained by using different material compositions for the base part 1312 and the top part 1314 of the barrier, only the base part 1312 may be formed in the substrate 1301 and should consist of the same material as the substrate. In this case, the preferred method of fabrication will be multi-cavity injection moulding.

Alternatively, poor wetting of the top part 1314 is obtained without using different material compositions. Instead, as shown in FIG. 14, the wetting properties of a top part 1414 of a barrier 1402 are obtained by forming at least a part of the surface of the top part 1414 with smaller raised structures 1415 as shown in FIG. 14. The small structures are typically formed as a pattern of small pillars and are also referred to as lotus leaf structure and are known to be extremely non-wetting. The small structures 1415 can be formed in the barrier 1402 using the materials and the fabrication techniques according to the invention. The barrier 1402 is again formed in a substrate (not shown).

The dimensions (cross-sectional area and height) of the lotus leaf structure are much smaller than the dimensions of the pixel. At present, the pixel size of a monochrome display is typically between 200-300 mm, while a color display is a factor of 3 smaller, i.e. 100-66 mm. In the future, however, this size will decrease to 50 mm, and maybe even smaller sizes, e.g. 25 mm. The dimensions of the lotus leaf structures (pillars) are important, whereas their cross-sectional shape can be anything from a square to a circle, or even more complicated patterns. The height of the pillars is preferably larger than half of the square root of the area, or, if possible, even larger.

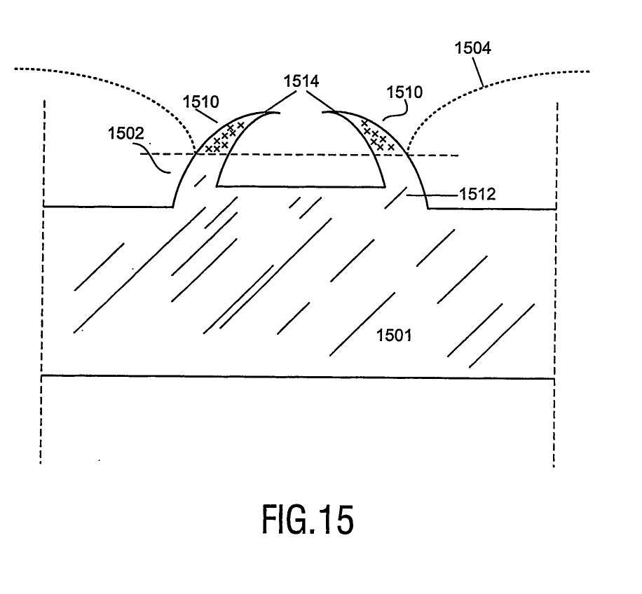

FIG. 15 illustrates a cross-section of a substrate 1501 according to the invention, showing a profile of a barrier 1502. Here, a top part of the barrier has both a detailed structuring and poor wetting properties. The barrier comprises two inward leaning barrier walls 1510 formed in order to prevent the liquid 1504 from spilling over into an adjacent channel. The barrier is also formed with different wetting properties as described in relation to FIG. 13. The surface of a base part 1512 of the barrier 1502 is characterized by good wetting properties, whereas the surface of a top part 1514 of the barrier 1502 is characterized by poor wetting properties.

In summary, the present invention provides a matrix substrate for controlling liquids printed on the substrate and a method of fabrication of such. According to the invention, a substrate holding a matrix of pixels for receiving and holding printed liquids is fabricated in a deformable and flexible polymeric material which allows for raised structures (barriers) separating the pixels to be formed in the substrate material itself. This renders possible a number of new methods of fabrication for the fabrication of matrix substrates, e.g. for use in polyLED displays. The materials and methods of fabrication according to the invention further remove a number of limitations in the freedom of design known from materials and methods of fabrication according to the prior art. This leads to the possibility of barrier profiles with overhanging structures, improved resolution and new dimension ranges.

1. A method for fabricating an article for receiving and holding droplets or lines of liquid deposition material, the method comprising the steps of:
providing a shaping tool having a surface part with a predetermined structure,
providing a deformable polymeric material, and
forming a structured surface part of the deformable polymeric material by processing the deformable polymeric material using the shaping tool, thereby forming a predetermined structure comprising a grid of raised structures (102, 302, 502, 602, 702, 802, 902, 1002, 1102, 1202, 1302, 1402, 1502) defining a matrix of compartments (107, 307, 707, 807, 907, 1007, 1207) in said surface part of the deformable polymeric material, said compartments being adapted to receive and hold droplets or lines of liquid deposition material, the structured surface part of the deformable polymeric material at least substantially being an imprint of the predetermined structure of said surface part of the shaping tool.

2. A method according to claim 1, wherein the deformable polymeric material, at least after the step of forming the structured surface part, forms a self-supporting substrate (101, 301, 501, 601, 701, 801, 901, 1001, 1101, 1201, 1301, 1501).

3. A method according to claim 1, wherein at least some of the raised structures are formed with a profile which allows for a compartment to hold a volume of the liquid which is larger than a volume of the compartment and which allows two adjacent compartments to be completely filled without mixing the liquids.

4. A method according to claim 1, wherein the shaping tool is a moulding form, and wherein the step of forming a structured surface part of the deformable polymeric material comprises the step of applying the deformable polymeric material into the moulding form.

5. A method according to claim 1, wherein the shaping tool is an embossing stamp, and wherein the step of forming a structured surface part of the deformable polymeric material comprises the step of embossing the deformable polymeric material with the embossing stamp.

6. A method according to claim 1, wherein the shaping tool is an extrusion form, and wherein the step of forming a structured surface part of the deformable polymeric material comprises the step of extruding the deformable polymeric material with the extrusion form.

7. A method according to claim 1, wherein the step of forming a structured surface part of the deformable polymeric material comprises the step of forming a surface part of a top part (1314, 1414, 1514) of the at least some raised structures in a hydrophobic material by multi-cavity injection moulding.

8. A shaping tool for use in the fabrication method according to the method of claim 1, the shaping tool having a surface part with a predetermined structure corresponding to a shape, profile, and intended function of the substrate.

9. A method for fabricating an article for receiving and holding droplets or lines of liquid deposition material, the method comprising the steps of:
providing a photopolymerisable material, and
forming a structured substrate (101, 301, 501, 601, 701, 801, 901, 1001, 1101, 1201, 1301, 1501) of the photopolymerisable material by photopolymerisation, comprising at least the steps of:
illuminating one or more first layers of said photopolymerisable material in a first predetermined pattern,
illuminating one or more second layers of said photopolymerisable material in a second predetermined pattern,
wherein the illuminated first layers form a substrate, and wherein the illuminated second layers form a grid of raised structures (102, 302, 502, 602, 702, 802, 902, 1002, 1102, 1202, 1302, 1402, 1502) defining a matrix of compartments (107, 307, 707, 807, 907, 1007, 1207) on said substrate, said compartments being adapted to receive and hold droplets or lines of liquid deposition material.

10. A method according to claim 9, wherein the step of forming a structured substrate of the photopolymerisable material further comprises the step of illuminating one or more further layers of said photopolymerisable material in one or more further predetermined patterns, thereby forming profiles of at least some of the raised structures, which profiles allow for a compartment to hold a volume of the liquid deposition material, which is larger than a volume of the compartment, and which allow two adjacent compartments to be completely filled without mixing the liquid deposition materials.

11. An article for receiving and holding droplets or lines of a liquid deposition material, the article comprising a substrate (101, 301, 501, 601, 701, 801, 901, 1001, 1101, 1201, 1301, 1501) formed by a deformable polymeric material, the substrate having a surface part comprising a grid of raised structures (102, 302, 502, 602, 702, 802, 902, 1002, 1102, 1202, 1302, 1402, 1502), the grid defining a matrix of compartments (107, 307, 707, 807, 907, 1007, 1207) being adapted to receive and hold droplets or lines of the liquid deposition material.

12. An article according to claim 11, wherein at least some of the raised structures have a profile which allows for a compartment to hold a volume of the liquid deposition material which is larger than a volume of the compartment, and which allows two adjacent compartments to be completely filled without mixing the liquid deposition materials.

13. An article according to claim 11, characterized in that the substrate is self-supporting.

14. An article according to claim 11, wherein at least some of the raised structures form elongated barriers separating a first (307) and a second (308) adjacent compartment, the profiles of said at least some raised structures having at least a first and a second edge, the first edge (311, 811, 911, 1011) being formed by atop surface (318) part and a side surface part (314) facing away from the second compartment, and the second edge (312, 812, 912, 1012) being formed by a top surface (305) part and a side surface part (315) facing away from the first compartment, the first edge being closer to the second compartment than the second edge and the second edge being closer to the first compartment than the first edge.

15. An article according to claim 14, wherein the top surface parts are at least substantially parallel to the substrate, and wherein the top surface parts and side surface parts forming the first and the second edge intersect at an angle θ smaller than 90° so as to form a sharp-pointed edge.

16. An article according to claim 11, wherein profiles of at least some of the raised structures comprise a pattern of small pillars (1415) having cross-sectional areas smaller than 10 μm² and heights larger than 1.6 μm.

17. An article according to claim 11, wherein profiles of at least some of the raised structures have cross-sectional areas smaller than 10 μm².

18. An article according to claim 11, wherein the profiles of at least some of the raised structures have cross-sectional areas smaller than 5 μm².

19. An article according to claim 11, wherein the profiles of at least some of the raised structures have cross-sectional areas smaller than 1 μm².

20. An article according to claim 11, wherein the heights of at least some of the raised structures are at least 10 μm.

21. An article according to claim 20, wherein the heights of at least some of the raised structures are at least 20 μm.

22. An article for receiving and holding droplets or lines of a liquid deposition material, the article comprising a substrate (101, 301, 501, 601, 701, 801, 901, 1001, 1101, 1201, 1301, 1501) formed by a deformable polymeric material and having a surface part comprising a grid of raised structures (102, 302, 502, 602, 702, 802, 902, 1002, 1102, 1202, 1302, 1402, 1502) formed at least partially in the substrate, at least some of the raised structures having a characteristic profile, the grid defining a matrix of compartments (107, 307, 707, 807, 907, 1007, 1207), wherein the raised structures enable the compartments to receive and hold droplets or lines of the liquid deposition material, and wherein the grid, the raised structures, and the characteristic profiles are formed by imprinting a shape of a shaping tool to the deformable polymeric material by a fabrication method selected from the group consisting of embossing, blow moulding, injection moulding, or extrusion.
